(19) United States
(12) Patent Application Publication
(10) Pub. No.: US 2023/0422473 A1
(43) Pub. Date: Dec. 28, 2023

(54) SEMICONDUCTOR-ELEMENT-INCLUDING MEMORY DEVICE

(71) Applicant: Unisantis Electronics Singapore Pte., Ltd., Singapore (SG)

(72) Inventors: Koji SAKUI, Tokyo (JP); Masakazu Kakumu, Tokyo (JP); Nozomu Harada, Tokyo (JP)

(21) Appl. No.: 18/337,988

(22) Filed: Jun. 20, 2023

(30) Foreign Application Priority Data
Jun. 23, 2022 (WO) PCT/JP2022/025073

(51) Int. Cl. H10B 12/00; G11C 11/404; G11C 11/408; G11C 11/4091; G11C 11/4096

(52) U.S. Cl. CPC H10B 12/20; G11C 11/404; G11C 11/4087; G11C 11/4091; G11C 11/4096

(57) ABSTRACT

A memory device includes pages arranged in a column direction and each constituted by memory cells arranged in a row direction on a substrate, each memory cell includes a semiconductor body, first and second impurity regions, and first and second gate conductor layers, the first and second impurity regions and first and second gate conductor layers are connected to source, bit, word, and plate lines respectively, and voltages applied to these lines are controlled to perform an erase operation of collecting a group of positive holes in the semiconductor body of a selected memory cell in a part adjacent to the first gate conductor layer and making some of the group of positive holes disappear and a page write operation of increasing by an impact ionization phenomenon, the number of positive holes in the semiconductor body of a selected memory cell in a page.

### CROSS REFERENCES TO RELATED APPLICATIONS

This application claims priority to PCT/JP2022/025073, filed Jun. 23, 2022, the entire content of which is incorporated herein by reference.

### BACKGROUND OF THE INVENTION

### 1. Field of the Invention

The present invention relates to a semiconductor-element-including memory device.

### 2. Description of the Related Art

Recently, there has been a demand for highly integrated and high-performance memory elements in the development of LSI (Large Scale Integration) technology.

High-density and high-performance memory elements are being developed. SGTs (Surrounding Gate Transistors, see Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) can be used as selection transistors for, for example, a DRAM (Dynamic Random Access Memory, see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)) to which a capacitor is connected, a PCM (Phase Change Memory, see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)) to which a resistance change element is connected, an RRAM (Resistive Random Access Memory, see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3V”, IEDM (2007)), and an MRAM (Magneto-resistive Random Access Memory, see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)) that changes the resistance by changing the orientation of a magnetic spin with a current.

There exists, for example, a DRAM memory cell (see Japanese Unexamined Patent Application Publication No. 3-171768, M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010), J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida: “A Capacitorless 1T-DRAM Technology Using Gate-Induced Drain Leakage (GIDL) Current for Low-Power and High-Speed Embedded Memory”, IEEE IEDM (2006)) constituted by a single MOS transistor and including no capacitor. For example, among a group of positive holes and electrons generated inside the channel by an impact ionization phenomenon caused by a current between the source and the drain of the N-channel MOS transistor, some or all of the group of positive holes are retained in the channel to write logical storage data “1”. The group of positive holes are discharged from inside the channel to write logical storage data “0”. With respect to the above-described memory cell, for a common selected word line, a memory cell to which “1” is written and a memory cell to which “0” is written are present at random. When an ON voltage is applied to the selected word line, the floating body channel voltage of a selected memory cell connected to the selected word line changes to a large degree due to capacitive coupling between the gate electrode and the channel. This memory cell has a problem that it experiences a decrease in the operation margin caused by the change in the floating body channel voltage and a decrease in the data retention performance caused by discharge of some of the group of positive holes that are signal charges stored in the channel, which are to be reduced.

There exist twin-transistor MOS transistor memory elements in which a single memory cell is formed in an SOI layer by using two MOS transistors (see, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4 pp. 765-771 (2007)). In these elements, an N⁺ layer that functions as the source or the drain and that separates the floating body channels of the two MOS transistors is formed so as to be in contact with an insulating layer that is on the substrate side. This N⁺ layer electrically isolates the floating body channels of the two MOS transistors from each other. A group of positive holes that are signal charges are stored only in the floating body channel of one of the MOS transistors. The other MOS transistor functions as a switch for reading the group of positive holes that are signal charges stored in the one of the MOS transistors. Also in this memory cell, the group of positive holes that are signal charges are stored in the channel of the one of the MOS transistors, and therefore, the memory cell has a problem that it experiences a decrease in the operation margin or a decrease in the data retention performance caused by discharge of some of the group of positive holes that are signal charges stored in the channel, which is to be reduced, as in the above-described memory cell constituted by a single MOS transistor.

There exists a dynamic flash memory cell 111 constituted by a MOS transistor and including no capacitor illustrated in FIG. 3A (see Japanese Patent No. 7057032 and K. Sakui, N. Harada, “Dynamic Flash Memory with Dual Gate Surrounding Gate Transistor (SGT)”, Proc. IEEE IMW, pp. 72-(2021)). As illustrated in FIG. 3A, a floating-body semiconductor body 102 is disposed on a SiO₂ layer 101 of an SOI substrate. An N⁺ layer 103 connected to a source line SL and an N⁺ layer 104 connected to a bit line BL are disposed at the respective ends of the floating-body semiconductor body 102. A first gate insulator layer 109a is connected to the N⁺ layer 103 and covers the floating-body semiconductor body 102, and a second gate insulator layer 109b is connected to the N⁺ layer 104, is connected to the first gate insulator layer 109a with a slit insulating film 110 therebetween, and covers the floating-body semiconductor body 102. A first gate conductor layer 105a covers the first gate insulator layer 109a and is connected to a plate line PL, and a second gate conductor layer 105b covers the second gate insulator layer 109b and is connected to a word line WL. Between the first gate conductor layer 105a and the second gate conductor layer 105b, the slit insulating layer 110 is disposed. These constitute the memory cell 111 of a DFM (dynamic flash memory). The source line SL may be connected to the N⁺ layer 104 and the bit line BL may be connected to the N⁺ layer 103.

As illustrated in FIG. 3A, for example, a zero voltage is applied to the N⁺ layer 103 and a positive voltage is applied to the N⁺ layer 104 to operate a first N-channel MOS transistor region that is a part of the floating-body semiconductor body 102 covered by the first gate conductor layer 105a in the saturation region and to operate a second N-channel MOS transistor region that is a part of the floating-body semiconductor body 102 covered by the second gate conductor layer 105b in the linear region. As a result, a pinch-off point is not present in the second N-channel MOS transistor region and an inversion layer 107b is formed on the entire surface. The inversion layer 107b that is formed below the second gate conductor layer 105b to which the word line WL is connected substantially functions as the drain of the first N-channel MOS transistor region. As a result, the electric field becomes maximum in a boundary region of the semiconductor body between the first N-channel MOS transistor region and the second N-channel MOS transistor region, and an impact ionization phenomenon occurs in this region. As illustrated in FIG. 3B, among a group of electrons and positive holes generated by the impact ionization phenomenon, the group of electrons are discharged from the floating-body semiconductor body 102 and some or all of a group of positive holes 106 are retained in the floating-body semiconductor body 102 to thereby perform a memory write operation. This state corresponds to logical storage data “1”.

As illustrated in FIG. 3C, for example, a positive voltage is applied to the plate line PL, a zero voltage is applied to the word line WL and the bit line BL, and a negative voltage is applied to the source line SL to discharge the group of positive holes 106 from the floating-body semiconductor body 102 and perform an erase operation. This state corresponds to logical storage data “0”. When the voltage applied to the first gate conductor layer 105a connected to the plate line PL is set to a voltage higher than a threshold voltage at the time of logical storage data “1” and lower than a threshold voltage at the time of logical storage data “0” in data reading, a property that a current does not flow even when the voltage of the word line WL is increased in reading of logical storage data “0” can be attained as illustrated in FIG. 3D. With this property, the operation margin can be increased to a large degree compared with the above-described memory cells. In the memory cell described here, the channels of the first and second N-channel MOS transistor regions respectively having the first gate conductor layer 105a connected to the plate line PL and the second gate conductor layer 105b connected to the word line WL as their gates are connected in the floating-body semiconductor body 102, which significantly reduces a change in the voltage of the floating-body semiconductor body 102 occurring in response to application of a selection pulse voltage to the word line WL. Accordingly, the decrease in the operation margin or the decrease in the data retention performance caused by discharge of some of the group of positive holes that are signal charges stored in the channel, which is a problem of the above-described memory cells, can be reduced to a large degree. In the future, further improvement of the properties of the memory element will be required.

### SUMMARY OF THE INVENTION

For a dynamic flash memory cell, a stable rewriting operation of the memory cell with low power consumption is required.

To address the above-described problems, a semiconductor-element-including memory device according to the present invention is
a memory device in which in plan view on a substrate, a plurality of pages are arranged in a column direction, each of the pages being constituted by a plurality of memory cells arranged in a row direction,
each of the memory cells included in each of the pages including:
a semiconductor body that stands on the substrate in a vertical direction or that extends along the substrate in a horizontal direction;
a first impurity region and a second impurity region that are disposed at respective ends of the semiconductor body;
a gate insulator layer that is in contact with a side surface of the semiconductor body between the first impurity region and the second impurity region;
a first gate conductor layer that partially or entirely covers the gate insulator layer; and
a second gate conductor layer that is adjacent to the first gate conductor layer and that is in contact with a side surface of the gate insulator layer, in which
voltages applied to the first impurity region, the second impurity region, the first gate conductor layer, and the second gate conductor layer are controlled to perform a page erase operation of collecting a majority of a group of positive holes in the semiconductor body of a selected memory cell in a part of the semiconductor body adjacent to one of the first gate conductor layer or the second gate conductor layer, making some of the group of positive holes disappear, and decreasing the number of positive holes and to perform a page write operation of increasing by an impact ionization phenomenon, the number of positive holes in the semiconductor body of a selected memory cell in a page among the pages, and
in the page erase operation, a ground voltage is applied to one of the first impurity region or the second impurity region, a positive voltage is applied to the other of the first impurity region or the second impurity region, and a positive voltage is applied to one of the first gate conductor layer or the second gate conductor layer on condition that the voltages are applied to the first impurity region, the second impurity region, the first gate conductor layer, and the second gate conductor layer such that a current does not flow between the first impurity region and the second impurity region in a steady state (first invention).

In the first invention described above, in the page erase operation, at least one page is selected, and all of the memory cells included in the selected page are simultaneously erased (second invention).

In the first invention described above, the first impurity region is connected to a source line, the second impurity region is connected to a bit line, one of the first gate conductor layer or the second gate conductor layer is connected to a word line, and the other of the first gate conductor layer or the second gate conductor layer is connected to a plate line, and
voltages applied to the source line, the bit line, the word line, and the plate line are controlled to perform the page write operation and the page erase operation (third invention).

In the third invention described above, in the page erase operation, a ground voltage is applied to the source line, a positive voltage is applied to the bit line, and a positive voltage is applied to one of the word line or the plate line, and subsequently, a positive voltage is applied to the other of the word line or the plate line on condition that the voltages are applied to the first impurity region, the second impurity region, the first gate conductor layer, and the second gate conductor layer such that a current does not flow between the first impurity region and the second impurity region in a steady state (fourth invention).

In the third invention described above, the word line and the plate line are disposed in parallel in plan view, and the bit line is disposed in a direction perpendicular to the word line and the plate line in plan view (fifth invention).

In the third invention described above, a first gate capacitance between the semiconductor body and the first gate conductor layer or the second gate conductor layer to which the plate line is connected is larger than a second gate capacitance between the semiconductor body and the first gate conductor layer or the second gate conductor layer to which the word line is connected (sixth invention).

In the third invention described above, in plan view, the source line includes isolated source lines that are disposed for respective groups of memory cells arranged in the column direction and that are disposed parallel to the word line and the plate line (seventh invention).

In the third invention described above, in plan view, the source line is disposed so as to be connected in common to all of the memory cells in pages adjacent to each other (eighth invention).

In the third invention described above, in plan view, the plate line is disposed so as to be shared between at least two or more pages adjacent to each other (ninth invention).

In the first invention described above, the semiconductor body is a P-type semiconductor layer, and the first impurity region and the second impurity region are N-type semiconductor layers (tenth invention).

In the first invention described above, in the page erase operation, selective erasing is performed for the memory cells in at least two pages (eleventh invention).

In the first invention described above, the first gate conductor layer is constituted by two divided gate conductor layers isolated from each other, and the divided gate conductor layers are positioned on respective sides of the second gate conductor layer, and
the page write operation and the page erase operation are performed (twelfth invention).

In the first invention described above, the second gate conductor layer is constituted by two divided gate conductor layers isolated from each other, and the divided gate conductor layers are positioned on respective sides of the first gate conductor layer, and
the page write operation and the page erase operation are performed (thirteenth invention).

In the third invention described above, the word line and the plate line are connected to a row decoder circuit, the row decoder circuit receives a row address, and a page is selected from among the pages in accordance with the row address (fourteenth invention).

In the third invention described above, the bit line is connected to a sense amplifier circuit, the sense amplifier circuit is connected to a column decoder circuit, the column decoder circuit receives a column address, and the sense amplifier circuit is selectively connected to an input/output circuit in accordance with the column address (fifteenth invention).

### BRIEF DESCRIPTION OF THE DRAWINGS

FIG. 1 is a structural diagram of an SGT-including memory device according to a first embodiment;

FIG. 2A is a diagram for explaining a mechanism of an erase operation of the memory device according to the first embodiment;

FIG. 2B is a diagram for explaining the mechanism of the erase operation of the memory device according to the first embodiment;

FIGS. 2CA, 2CB and 2CC are diagrams for explaining the mechanism of the erase operation of the memory device according to the first embodiment;

FIG. 2D is a diagram for explaining the mechanism of the erase operation of the memory device according to the first embodiment;

FIG. 2E is a diagram for explaining the mechanism of the erase operation of the memory device according to the first embodiment;

FIG. 2F is a diagram for explaining the mechanism of the erase operation of the memory device according to the first embodiment;

FIG. 2G is a diagram for explaining the mechanism of the erase operation of the memory device according to the first embodiment; and

FIGS. 3A, 3B, 3C and 3D are diagrams for explaining a dynamic flash memory in the related art.

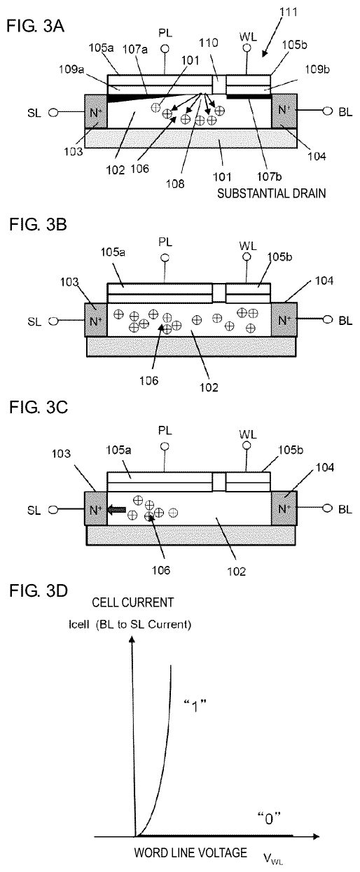

### DESCRIPTION OF THE PREFERRED EMBODIMENTS

Hereinafter, a semiconductor-element-including memory device (hereinafter called a dynamic flash memory) according to embodiments of the present invention will be described with reference to the drawings.

### First Embodiment

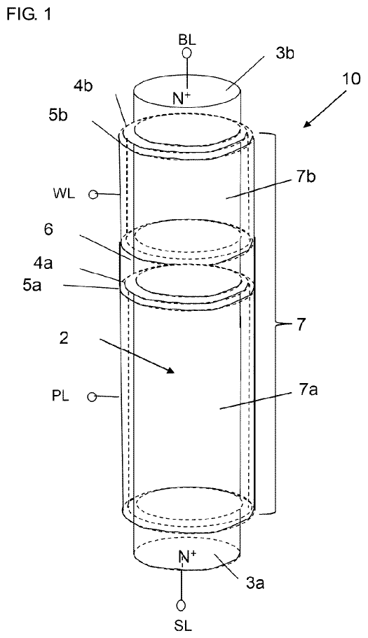

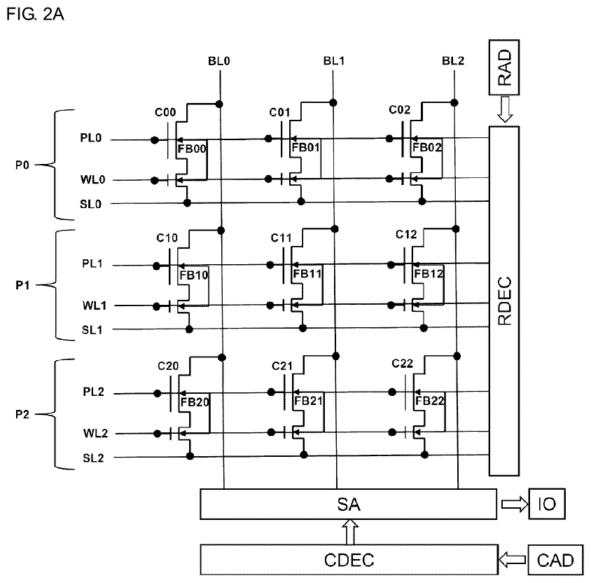

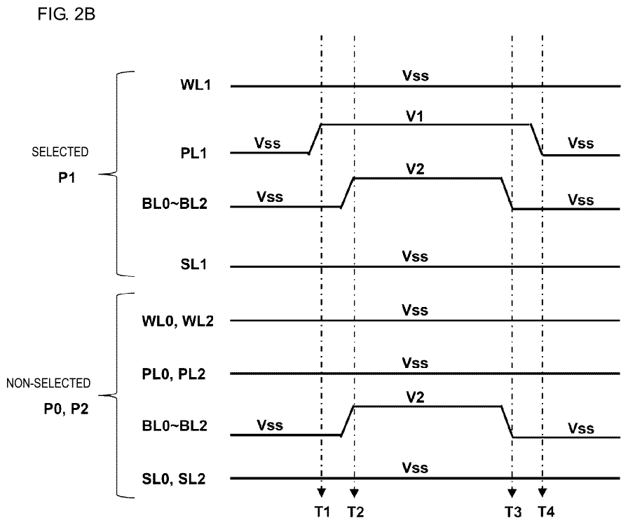

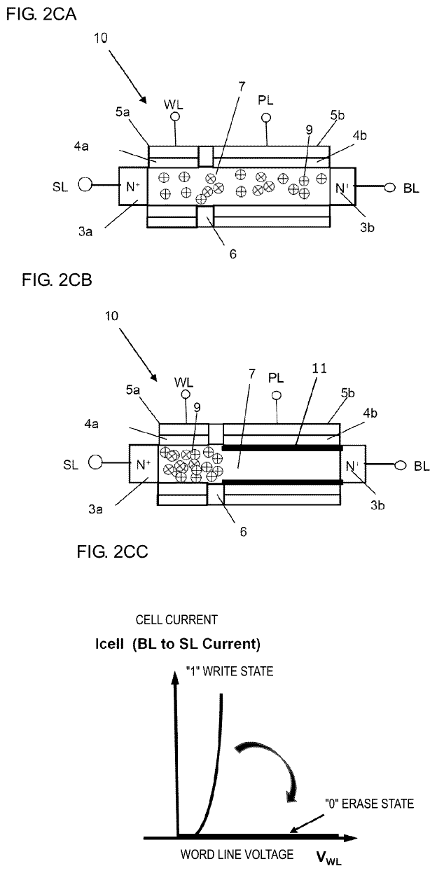

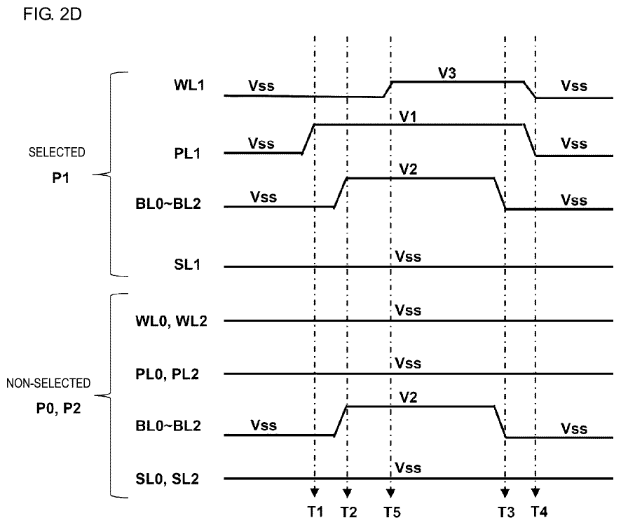

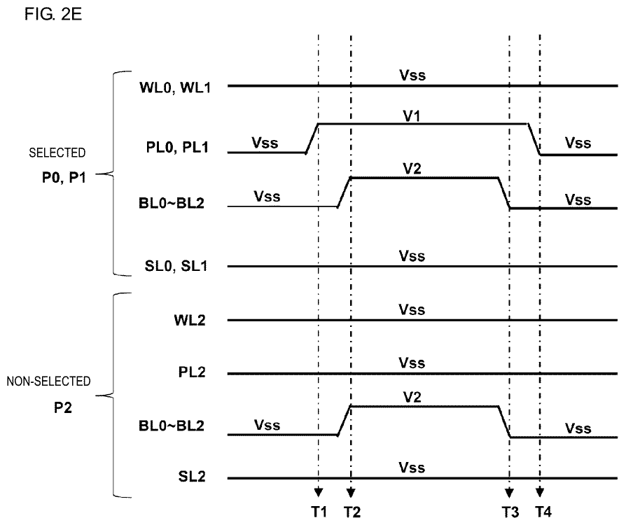

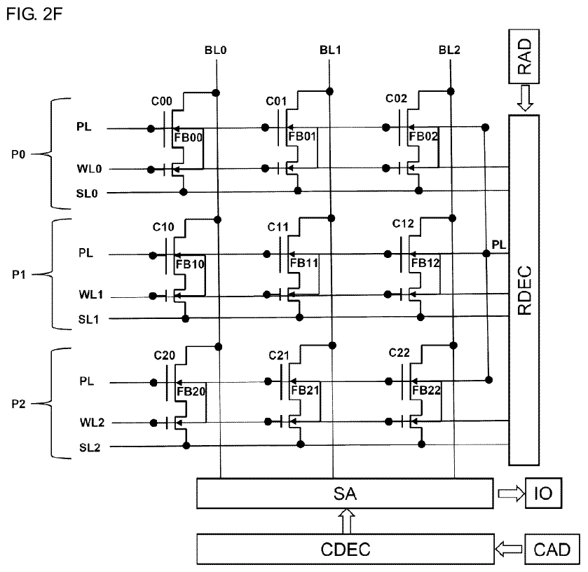

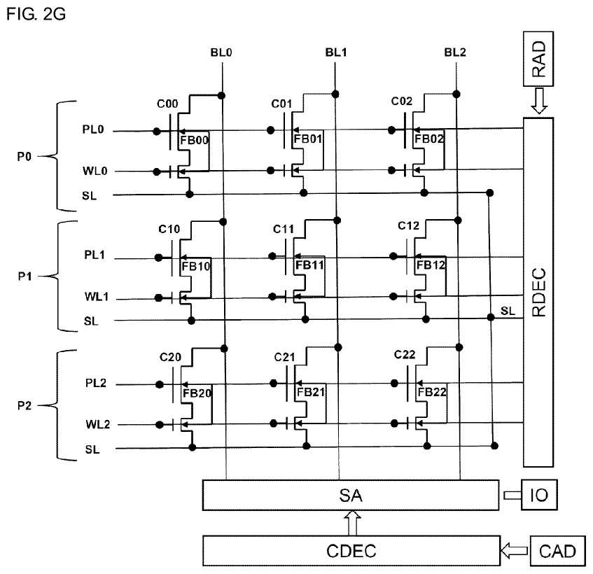

The structure and operation mechanisms of a dynamic flash memory cell according to a first embodiment of the present invention will be described with reference to FIG. 1 and FIGS. 2A to 2G. The structure of the dynamic flash memory cell will be described with reference to FIG. 1. A mechanism of an erase operation will be described with reference to FIGS. 2A to 2G.

FIG. 1 illustrates the structure of the dynamic flash memory cell according to the first embodiment of the present invention. On the top and the bottom of a silicon semiconductor column 2 (the silicon semiconductor column is hereinafter referred to as “Si column”) (which is an example of “semiconductor body” in the claims) of the P or i (intrinsic) conductivity type formed on a substrate, N⁺ layers 3a and 3b (which are examples of “first impurity region” and “second impurity region” in the claims), one of which functions as the source and the other functions as the drain, are formed respectively. The part of the Si column 2 between the N⁺ layers 3a and 3b that function as the source and the drain functions as a semiconductor body 7 (which is an example of “semiconductor body” in the claims). Around the semiconductor body 7, a first gate insulator layer 4a (which is an example of “first gate insulator layer” in the claims) and a second gate insulator layer 4b (which is an example of “second gate insulator layer” in the claims) are formed. The first gate insulator layer 4a and the second gate insulator layer 4b are in contact with or in close vicinity to the N⁺ layers 3a and 3b that function as the source and the drain respectively. Around the first gate insulator layer 4a and the second gate insulator layer 4b, a first gate conductor layer 5a (which is an example of “first gate conductor layer” in the claims) and a second gate conductor layer 5b (which is an example of “second gate conductor layer” in the claims) are formed respectively. The first gate conductor layer 5a and the second gate conductor layer 5b are isolated from each other by an insulating layer 6. The semiconductor body 7 between the N⁺ layers 3a and 3b is constituted by a first semiconductor body 7a surrounded by the first gate insulator layer 4a and a second semiconductor body 7b surrounded by the second gate insulator layer 4b. Accordingly, the N⁺ layers 3a and 3b that function as the source and the drain, the semiconductor body 7, the first gate insulator layer 4a, the second gate insulator layer 4b, the first gate conductor layer 5a, and the second gate conductor layer 5b constitute a dynamic flash memory cell 10. The N⁺ layer 3a that functions as the source is connected to a source line SL (which is an example of “source line” in the claims), the N⁺ layer 3b that functions as the drain is connected to a bit line BL (which is an example of “bit line” in the claims), the first gate conductor layer 5a is connected to a plate line PL (which is an example of “plate line” in the claims), and the second gate conductor layer 5b is connected to a word line WL (which is an example of “word line” in the claims). Desirably, the dynamic flash memory cell has a structure in which a first gate capacitance (which is an example of “first gate capacitance” in the claims) of the first gate conductor layer 5a to which the plate line PL is connected is larger than a second gate capacitance (which is an example of “second gate capacitance” in the claims) of the second gate conductor layer 5b to which the word line WL is connected. Note that one of the first gate conductor layer or the second gate conductor layer 5b may be divided into two gate conductor layers. In this case, it is desirable to dispose the divided two gate conductor layers on the respective sides of the first gate conductor layer 5a or the second gate conductor layer 5b that is not divided.

With reference to FIG. 2A to FIG. 2G, a mechanism of an erase operation (which is an example of “erase operation” in the claims) will be described.

FIG. 2A is a memory block diagram including main circuits for explaining the erase operation. Word lines WL0 to WL2 and plate lines PL0 to PL2 are connected to a row decoder circuit RDEC (which is an example of “row decoder circuit” in the claims), the row decoder circuit receives a row address RAD (which is an example of “row address” in the claims), and selection from pages P0 to P2 is made in accordance with the row address RAD. Bit lines BL0 to BL2 are connected to a sense amplifier circuit SA, the sense amplifier circuit SA is connected to a column decoder circuit CDEC (which is an example of “column decoder circuit” in the claims), the column decoder circuit CDEC receives a column address CAD (which is an example of “column address” in the claims), and the sense amplifier circuit SA (which is an example of “sense amplifier circuit” in the claims) is selectively connected to an input/output circuit IO (which is an example of “input/output circuit” in the claims) in accordance with the column address CAD.

Unlike in FIG. 1, the plate lines PL0 to PL2 are disposed adjacent to the bit lines BL0 to BL2, and the word lines WL0 to WL2 are disposed adjacent to source lines SL0 to SL2 for dynamic flash memory cells that constitute the memory block illustrated in FIG. 2A. Although nine memory cells C00 to C22 in three rows and three columns in plan view are illustrated, the number of memory cells included in the actual memory block is larger than nine. When memory cells are arranged in a matrix, one of the directions of the arrangement is called “row direction” (or “in rows”) and the direction perpendicular to the one of the directions is called “column direction” (or “in columns”). The source lines SL0 to SL2, the plate lines PL0 to PL2, and the word lines WL0 to WL2 are disposed in parallel, and the bit lines BL0 to BL2 are disposed in a direction perpendicular to the source lines SL0 to SL2, the plate lines PL0 to PL2, and the word lines WL0 to WL2. For example, it is assumed that the memory cells C10 to C12, in a specific page P1, to which the plate line PL1, the word line WL1, and the source line SL1 are connected are selected in this block and the erase operation is performed. Similarly, the memory cells in a specific page can be selected and a page write operation (which is an example of “page write operation” in the claims) and a page read operation can be performed.

FIG. 2B is an operation waveform diagram of the erase operation. A case where the erase operation starts and, for example, selective erasing of the page P1 is performed will be described. At a first time T1, the plate line PL1 rises from a ground voltage Vss to a first voltage V1. Here, the ground voltage Vss is equal to, for example, 0 V. The first voltage V1 is equal to, for example, 2 V and is a voltage with which the N-channel MOS transistor region in which the semiconductor body is surrounded by the plate line PL1 operates in the linear region. Next, at a second time T2, the bit lines BL0 to BL2 rise from the ground voltage Vss to a second voltage V2. Here, the second voltage V2 is equal to, for example, 0.6 V. For the memory cells C10 to C12 for which the erase operation is performed, Vss, which is an OFF voltage, is applied to the word line WL1 in this period, and therefore, a current does not flow between the source line SL1 and the bit lines BL0 to BL2 in a steady state when the above-described voltages are applied.

The mechanism of a page erase operation in which a negative voltage is not input to any of the source line SL, the bit line BL, the plate line PL, and the word line WL will be described with reference to FIGS. 2CA to 2CC. FIG. 2CA illustrates a state in which a voltage of 0 V is applied to the bit line BL, 0 V is applied to the source line SL, 0 V is applied to the plate line PL, and 0 V is applied to the word line WL. When a voltage of 0.6 V is applied to the bit line BL, 0 V is applied to the source line SL, 2 V is applied to the plate line PL, and 0 V is applied to the word line WL in this state, the majority of a group of positive holes 9 having positive charges collect in a part adjacent to the first gate conductor layer 5a connected to the word line WL to which 0 V is applied from a part adjacent to the plate line PL to which 2 V is applied. As a result, the voltage of the semiconductor body 7 surrounded by the word line WL rises. Therefore, the PN junction between the N⁺ layer 3a of the source line SL and the P-layer semiconductor body 7 is forward biased, and the group of positive holes 9 that are excessive are discharged to the N⁺ layer 3a of the source line SL. The concentration of the group of positive holes 9 collecting in the P-layer semiconductor body 7 in a part adjacent to the word line WL is sufficiently higher than the concentration of positive holes facing the N⁺ layer 3a, and therefore, the concentration gradient causes diffusion of the group of positive holes 9, and the group of positive holes 9 flow into the N⁺ layer 3a. In contrast, the concentration of electrons in the N⁺ layer 3a is higher than the concentration of electrons in the P-layer semiconductor body 7, and therefore, with diffusion caused by the concentration gradient, the electrons flow into the P-layer semiconductor body 7. The electrons having flowed into the P-layer semiconductor body 7 recombine with positive holes inside the P-layer semiconductor body 7 and disappear. However, all of the entering electrons do not disappear, and electrons that do not disappear flow into the N⁺ layer 3b of the bit line BL by a drift. Electrons are successively supplied from the source line SL, and therefore, excessive positive holes recombine with the electrons in a very short time, which results in a return to the initial state. Here, electric power is consumed only by the electrons entering from the source line SL and a current does not steadily flow between the N⁺ layers 3a and 3b, and therefore, the power consumption is very low compared with power consumption during the page write operation. Accordingly, the threshold voltages of the N-channel MOS transistor regions in which the semiconductor body 7 is surrounded by the word line WL and the plate line PL are increased. Therefore, as illustrated in FIG. 2CC, a current does not flow even when the voltage of the word line WL is increased. The page erase operation in which a voltage V_{FB} “0” in the “0” erase state of the semiconductor body 7 is assumed to be a first data retention voltage is performed to assign logical storage data “0”.

As illustrated in FIG. 2CB, in the page erase operation, an inversion layer 11 is formed in an outer periphery portion of the semiconductor body 7 surrounded by the second gate conductor layer 5b connected to the plate line PL. The inversion layer 11 is connected to the N⁺ layer 3b and has a large number of electrons. Accordingly, in the initial period of the page erase operation, some of the group of positive holes 9 inside the semiconductor body 7 surrounded by the inversion layer 11 can be discharged by a positive hole-electron recombination phenomenon. As a result, the page erase operation is further accelerated.

When the discharge of the group of positive holes 9 stored in the semiconductor body 7 reaches saturation, the bit lines BL0 to BL2 return from the second voltage V2 to the ground voltage Vss at a third time T3 illustrated in FIG. 2B, the plate line PL1 returns from the first voltage V1 to the ground voltage Vss at a fourth time T4, and the page erase operation ends.

As illustrated in FIG. 2D, at a fifth time 15 after the second time T2 in FIG. 2B, the word line WL1 may be made to rise from the ground voltage Vss to a third voltage V3. Here, the third voltage V3 is equal to, for example, 0.6 V. With an electric field from the word line WL1 to the semiconductor body 7, the PN junction between the N⁺ layer 3a of the source line SL and the P-layer semiconductor body 7 is forward biased again, and the group of positive holes 9 that are excessive are further discharged to the N⁺ layer 3a of the source line SL. As a result, the threshold voltages of the N-channel MOS transistor regions in which the semiconductor body 7 is surrounded by the word line WL1 and the plate line PL1 are further increased.

As illustrated in FIG. 2E, two pages P0 and P1 or more may be selected and the erase operation may be performed for the pages simultaneously. For example, when 1 kb (1024) pages are included in a memory block, a block erase operation may be performed for the entire block. This is because the erase operation can be performed with a very small current far smaller than a current used in the page write operation. This can significantly increase a system speed of, for example, block rewriting.

As illustrated in FIG. 2F, the plate line PL is disposed so as to be connected in common to the memory cells in pages adjacent to each other. As illustrated in FIG. 2G, the source line SL may be disposed so as to be connected in common to all of the memory cells in pages adjacent to each other. These make the design and processes more flexible.

Note that driving performed in a case where each of the first gate conductor layer 7a and the second gate conductor layer 7b illustrated in FIG. 1 is constituted by one gate conductor layer has been described with reference to FIG. 2A to FIG. 2G. In contrast, in a case where one of the first gate conductor layer 5a or the second gate conductor layer 5b is divided into two gate conductor layers and the divided two gate conductor layers are disposed on the respective sides of the first gate conductor layer 5a or the second gate conductor layer 5b that is not divided, the voltages illustrated in FIG. 2A to FIG. 2G are applied to at least one of the divided two gate conductor layers. Accordingly, the operations of the dynamic flash memory cell are normally performed.

Regardless of whether the horizontal cross-sectional shape of the Si column 2 illustrated in FIG. 1 is a round shape, an elliptic shape, or a rectangular shape, the operations of the dynamic flash memory described in this embodiment can be performed. Further, a dynamic flash memory cell having a round shape, a dynamic flash memory cell having an elliptic shape, and a dynamic flash memory cell having a rectangular shape may coexist on the same chip.

With reference to FIG. 1, the dynamic flash memory element including, for example, an SGT in which the first gate insulator layer 4a and the second gate insulator layer 4b that surround the entire side surface of the Si column 2 standing on the substrate in the vertical direction are provided and which includes the first gate conductor layer 5a and the second gate conductor layer 5b that entirely surround the first gate insulator layer 4a and the second gate insulator layer 4b has been described. As indicated in the description of this embodiment, the dynamic flash memory element needs to have a structure that satisfies the condition that the group of positive holes 9 generated by an impact ionization phenomenon are retained in the semiconductor body 7. For this, the semiconductor body 7 needs to have a floating body structure isolated from the substrate. Accordingly, even when the semiconductor body is formed horizontally along the substrate (such that the central axis of the semiconductor body is parallel to the substrate) by using, for example, GAA (Gate All Around, see, for example, J. Y. Song, W. Y. Choi, J. H. Park, J. D. Lee, and B-G. Park: “Design Optimization of Gate-All-Around (GAA) MOSFETs”, IEEE Trans. Electron Devices, vol. 5, no. 3, pp. 186-191, (2006)) technology, which is one type of SGT, or nanosheet technology (see, for example, N. Loubet, et al.: “Stacked Nanosheet Gate-All-Around Transistor to Enable Scaling Beyond FinFET”, 2017 IEEE Symposium on VLSI Technology Digest of Technical Papers, T17-5, T230-T231, (2017)), the above-described operations of the dynamic flash memory can be performed. The dynamic flash memory element may have a structure in which a plurality of GAA transistors or nanosheets formed in the horizontal direction are stacked. Alternatively, the dynamic flash memory element may have a device structure using SOI (Silicon On Insulator) (see, for example, J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida: “A Capacitorless 1T-DRAM Technology Using Gate-Induced Drain Leakage (GIDL) Current for Low-Power and High-Speed Embedded Memory”, IEEE IEDM (2006)). In this device structure, the bottom portion of the semiconductor body is in contact with an insulating layer of the SOI substrate, and the other portion of the semiconductor body is surrounded by a gate insulator layer and an element isolation insulating layer. With such a structure, the semiconductor body also has a floating body structure. Accordingly, the dynamic flash memory element provided in this embodiment needs to satisfy the condition that the semiconductor body has a floating body structure. Even with a structure in which a Fin transistor (see, for example, H. Jiang, N. Xu, B. Chen, L. Zengl, Y. He, G. Du, X. Liu and X. Zhang: “Experimental investigation of self-heating effect (SHE) in multiple-fin SOI FinFETs”, Semicond. Sci. Technol. 29 115021 pp. 7 (2014)) is formed on an SOI substrate, as long as the semiconductor body has a floating body structure, the operations of the dynamic flash memory can be performed.

Although FIG. 2A to FIG. 2G and the descriptions thereof illustrate example conditions of the erase operation, the voltages applied to the source line SL, the plate line PL, the bit line BL, and the word line WL may be changed as long as a state in which the group of positive holes 9 in the semiconductor body 7 are discharged through one or both of the N⁺ layer 3a and the N⁺ layer 3b can be attained.

In FIG. 1, in a direction perpendicular to the substrate, in a part of the semiconductor body 7 surrounded by the insulating layer 6, the potential distribution of the first semiconductor body 7a and that of the second semiconductor body 7b are connected and formed. Accordingly, the first semiconductor body 7a and the second semiconductor body 7b that constitute the semiconductor body 7 are connected in the vertical direction in the region surrounded by the insulating layer 6.

In FIG. 1, it is desirable to make the length of the first gate conductor layer 5a, in the vertical direction, to which the plate line PL is connected further longer than the length of the second gate conductor layer in the vertical direction, to which the word line WL is connected to attain C_{PL}>C_{WL}. However, when the plate line PL is only added, the capacitive coupling ratio (C_{WL}/(C_{PL}+C_{WL}+C_{BL}+C_{SL})) of the word line WL to the semiconductor body 7 decreases. As a result, the potential change ΔV_{FB} of the semiconductor body 7 that is a floating body decreases.

In the specification and the claims, the meaning of “cover” in a case of “a gate insulator layer, a gate conductor layer, or the like covers a channel or the like” also includes a case of surrounding entirely as in an SGT or GAA, a case of surrounding except a portion as in a Fin transistor, and a case of overlapping a flat object as in a planar transistor.

Although the first gate conductor layer 5a entirely surrounds the first gate insulator layer 4a in FIG. 1, a structure may be employed in which the first gate conductor layer 5a partially surrounds the first gate insulator layer 4a in plan view. The first gate conductor layer 5a may be divided into at least two gate conductor layers, and the gate conductor layers may each be operated as an electrode of the plate line PL. Similarly, the second gate conductor layer 5b may be divided into two or more gate conductor layers, and the gate conductor layers may each function as a conductive electrode of the word line and may be operated synchronously or asynchronously. One or both of the first gate conductor layer 5a and the second gate conductor layer 5b may be divided into two or more isolated gate conductor layers in plan view or in the vertical direction, and the isolated gate conductor layers may be operated synchronously or asynchronously. In the vertical direction, the isolated gate conductor layers obtained from one of the first gate conductor layer 5a or the second gate conductor layer 5b may be disposed on the respective sides of the other of the first gate conductor layer 5a or the second gate conductor layer 5b. In this case, the operations of the dynamic flash memory can be performed.

In FIG. 1, the first gate conductor layer 5a may be connected to the word line WL and the second gate conductor layer 5b may be connected to the plate line PL. In this case, the above-described operations of the dynamic flash memory can also be performed.

This embodiment has the following features.

### Feature 1

A feature of the dynamic flash memory cell according to the first embodiment of the present invention is the erase operation. In the erase operation, a negative voltage need not be applied to, for example, the source line SL or the bit line BL. As a result, for example, a negative charge pump or a twin well structure need not be provided, which can allow a significant reduction in chip size and manufacturing costs. This can attain a decrease in costs of the memory device. A negative charge pump is not necessary, and therefore, this can attain lower power consumption. In addition, when a positive voltage and a negative voltage coexist in a memory core circuit, charging of a high-capacitance well for interrupting a negative voltage is not necessary, and this allows a significant increase in speed and a reduction in power consumption.

### Feature 2

The source line SL, the word line WL, and the plate line PL are disposed parallel to each page P. A negative voltage is not used in the circuit operations of the memory block. As a result, the word line WL, the plate line PL, and the source line SL for controlling each page can be controlled independently on a page-by-page basis. At the time of the page erase operation, the word line WL, the plate line PL, and the source line SL of a non-selected page can be set at the ground voltage Vss. Accordingly, a disturbance to the non-selected page created by the selected page in the page erase operation can be satisfactorily prevented. Therefore, even when a specific page is selected a plurality of times and the storage data in the memory cells of the page is repeatedly rewritten, the memory cells of the other pages are not affected by a disturbance, and a highly reliable memory device having significantly strong resilience to a disturbance cycle can be provided.

### Feature 3

In the present invention, the erase operation does not need a steady-state current flowing between the bit line BL and the source line SL of the memory cell. As a result, not only simultaneous erasing of a plurality of pages but also a block erase operation of the entire block when the memory block includes, for example, 1 kb (1024) pages can be performed. This can significantly increase a system speed of, for example, block rewriting.

### Other Embodiments

Although the Si column is formed in the present invention, a semiconductor column made of a semiconductor material other than Si may be formed. The same applies to other embodiments according to the present invention.

To write “1”, electron-positive hole pairs may be generated by an impact ionization phenomenon using a gate-induced drain leakage (GIDL) current described in E. Yoshida: “A Capacitorless 1T-DRAM Technology Using Gate-Induced Drain Leakage (GIDL) Current for Low-Power and High-Speed Embedded Memory”, IEEE IEDM (2006), and the floating body FB may be filled with the generated group of positive holes. The same applies to other embodiments according to the present invention.

Even with a structure in which the polarity of the conductivity type of each of the N⁺ layers 3a and 3b and the P-layer Si column 2 in FIG. 1 is reversed, the operations of the dynamic flash memory can be performed. In this case, in the Si column 2 that is of N-type, the majority carriers are electrons. Therefore, a group of electrons generated by impact ionization are stored in the semiconductor body 7, and a “1” state is set.

The Si columns of the memory cells may be arranged in two dimensions in a square lattice or in a diagonal lattice to form a memory block. When the Si columns are disposed in a diagonal lattice, the Si columns connected to one word line may be disposed in a zigzag pattern or a serrated pattern in which each segment is constituted by a plurality of Si columns. The same applies to other embodiments.

Various embodiments and modifications can be made to the present invention without departing from the spirit and scope of the present invention in a broad sense. The above-described embodiments are intended to explain examples of the present invention and are not intended to limit the scope of the present invention. Any of the above-described embodiments and modifications can be combined. Further, the above-described embodiments from which some of the configuration requirements are removed as needed are also within the scope of the technical spirit of the present invention.

With the semiconductor-element-including memory device according to the present invention, a high-density and high-performance dynamic flash memory that is an SGT-including memory device can be obtained.

What is claimed is:

1. A semiconductor-element-including memory device that is a memory device in which in plan view on a substrate, a plurality of pages are arranged in a column direction, each of the pages being constituted by a plurality of memory cells arranged in a row direction,
each of the memory cells included in each of the pages comprising:
a semiconductor body that stands on the substrate in a vertical direction or that extends along the substrate in a horizontal direction;
a first impurity region and a second impurity region that are disposed at respective ends of the semiconductor body;
a gate insulator layer that is in contact with a side surface of the semiconductor body between the first impurity region and the second impurity region;
a first gate conductor layer that partially or entirely covers the gate insulator layer; and
a second gate conductor layer that is adjacent to the first gate conductor layer and that is in contact with a side surface of the gate insulator layer, wherein
voltages applied to the first impurity region, the second impurity region, the first gate conductor layer, and the second gate conductor layer are controlled to perform a page erase operation of collecting a majority of a group of positive holes in the semiconductor body of a selected memory cell in a part of the semiconductor body adjacent to one of the first gate conductor layer or the second gate conductor layer, making some of the group of positive holes disappear, and decreasing the number of positive holes and to perform a page write operation of increasing by an impact ionization phenomenon, the number of positive holes in the semiconductor body of a selected memory cell in a page among the pages, and
in the page erase operation, a ground voltage is applied to one of the first impurity region or the second impurity region, a positive voltage is applied to the other of the first impurity region or the second impurity region, and a positive voltage is applied to one of the first gate conductor layer or the second gate conductor layer on condition that the voltages are applied to the first impurity region, the second impurity region, the first gate conductor layer, and the second gate conductor layer such that a current does not flow between the first impurity region and the second impurity region in a steady state.

2. The semiconductor-element-including memory device according to claim 1, wherein
in the page erase operation, at least one page is selected, and all of the memory cells included in the selected page are simultaneously erased.

3. The semiconductor-element-including memory device according to claim 1, wherein
the first impurity region is connected to a source line, the second impurity region is connected to a bit line, one of the first gate conductor layer or the second gate conductor layer is connected to a word line, and the other of the first gate conductor layer or the second gate conductor layer is connected to a plate line, and
voltages applied to the source line, the bit line, the word line, and the plate line are controlled to perform the page write operation and the page erase operation.

4. The semiconductor-element-including memory device according to claim 3, wherein
in the page erase operation, a ground voltage is applied to the source line, a positive voltage is applied to the bit line, and a positive voltage is applied to one of the word line or the plate line, and subsequently, a positive voltage is applied to the other of the word line or the plate line on condition that the voltages are applied to the first impurity region, the second impurity region, the first gate conductor layer, and the second gate conductor layer such that a current does not flow between the first impurity region and the second impurity region in a steady state.

5. The semiconductor-element-including memory device according to claim 3, wherein
the word line and the plate line are disposed in parallel in plan view, and
the bit line is disposed in a direction perpendicular to the word line and the plate line in plan view.

6. The semiconductor-element-including memory device according to claim 3, wherein
a first gate capacitance between the semiconductor body and the first gate conductor layer or the second gate conductor layer to which the plate line is connected is larger than a second gate capacitance between the semiconductor body and the first gate conductor layer or the second gate conductor layer to which the word line is connected.

7. The semiconductor-element-including memory device according to claim 3, wherein
in plan view, the source line includes isolated source lines that are disposed for respective groups of memory cells arranged in the column direction and that are disposed parallel to the word line and the plate line.

8. The semiconductor-element-including memory device according to claim 3, wherein
in plan view, the source line is disposed so as to be connected in common to all of the memory cells in pages adjacent to each other.

9. The semiconductor-element-including memory device according to claim 3, wherein
in plan view, the plate line is disposed so as to be shared between at least two or more pages adjacent to each other.

10. The semiconductor-element-including memory device according to claim 1, wherein
the semiconductor body is a P-type semiconductor layer, and the first impurity region and the second impurity region are N-type semiconductor layers.

11. The semiconductor-element-including memory device according to claim 1, wherein
in the page erase operation, selective erasing is performed for the memory cells in at least two pages.

12. The semiconductor-element-including memory device according to claim 1, wherein
the first gate conductor layer is constituted by two divided gate conductor layers isolated from each other, and the divided gate conductor layers are positioned on respective sides of the second gate conductor layer, and
the page write operation and the page erase operation are performed.

13. The semiconductor-element-including memory device according to claim 1, wherein
the second gate conductor layer is constituted by two divided gate conductor layers isolated from each other, and the divided gate conductor layers are positioned on respective sides of the first gate conductor layer, and
the page write operation and the page erase operation are performed.

14. The semiconductor-element-including memory device according to claim 3, wherein
the word line and the plate line are connected to a row decoder circuit, the row decoder circuit receives a row address, and a page is selected from among the pages in accordance with the row address.

15. The semiconductor-element-including memory device according to claim 3, wherein
the bit line is connected to a sense amplifier circuit, the sense amplifier circuit is connected to a column decoder circuit, the column decoder circuit receives a column address, and the sense amplifier circuit is selectively connected to an input/output circuit in accordance with the column address.
